(19) United States
(12) Patent Application Publication
(10) Pub. No.: US 2009/0105983 A1
(43) Pub. Date: Apr. 23, 2009

(54) TEST DEFINER, A METHOD OF AUTOMATICALLY DETERMINING AND REPRESENTING FUNCTIONAL TESTS FOR A PCB HAVING ANALOG COMPONENTS AND A TEST SYSTEM

(75) Inventors: Pramod Variyam, Plano, TX (US); Sudhir Wokhlu, Plano, TX (US); Srividya Sundar, Tuscaloosa, AL (US); Venkat Kalyanaraman, Richardson, TX (US); Bruce Kim, Tuscaloosa, AL (US); Raul I. Rousselin, Wylie, TX (US); Toby O. Byrd, Honey Grove, TX (US); Erika L. Beskar, Allen, TX (US)

Correspondence Address: TEXAS INSTRUMENTS INCORPORATED, P O BOX 655474, M/S 3999, DALLAS, TX, 75265, US

(73) Assignee: Texas Instruments Incorporated, Dallas, TX (US)

(21) Appl. No.: 12/255,534

(22) Filed: Oct. 21, 2008

Related U.S. Application Data
(60) Provisional application No. 60/982,030, filed on Oct. 23, 2007.

(51) Int. Cl. G01R 31/28

(52) U.S. Cl. 702/124

(57) ABSTRACT

A test definer, a method for automatically determining functional tests for a printed circuit board (PCB) having analog components and a test system. In one embodiment, the test definer includes: (1) a circuit builder configured to generate a representative circuit of the PCB based on schematic information thereof, (2) a circuit organizer configured to partition the representative circuit into testable sub-circuits and (3) a specification generator configured to automatically determine functionality tests for the PCB based on the sub-circuits, obtain expected values from the functionality tests and generate platform-independent specifications representing the functionality tests and the expected values.

### CROSS-REFERENCE TO RELATED APPLICATION

This application claims the benefit of U.S. Provisional Application No. 60/982,030 entitled “Low Cost Automatic Mixed-Signal Board Test Using IEEE 1149.4,” by Sudhir Wokhlu, et al., filed on Oct. 23, 2007, which is incorporated herein by reference as if reproduced herein in its entirety. This application is also related to U.S. patent application Ser. No. 11/675,558, by Sudhir Wokhlu, et al. U.S. patent application Ser. No. 11/675,558 is commonly assigned with this application and is incorporated herein by reference in its entirety.

### TECHNICAL FIELD OF THE INVENTION

The invention is directed, in general, to testing printed circuit boards (PCBs) and, more specifically, to functional testing of PCBs having analog components.

### BACKGROUND OF THE INVENTION

Semiconductor devices, such as integrated circuits (ICs) used in a wireless apparatus, are tested throughout the development process to determine compliance with specifications and locate defects. Validation of packaged ICs includes bench characterization to test for functionality and performance compliance. One way to perform bench characterization testing is to connect the IC to be tested to a device interface board (DIB) to provide an interface between a test infrastructure and the IC.

A conventional wireless handset device usually has multiple mixed-signal or analog ICs, called a chipset. To adequately test a chipset, the needed DIB is typically a complicated circuit board that is uniquely designed for each IC in the chipset that is to be tested. A mixed-signal DIB used for first silicon characterization is complicated due to the increase in components such as active switches, discrete transistors, diodes, jumpers and SubMiniature version A (SMA) connectors. To insure accuracy of the IC testing, each DIB needs to be verified fault free before used in the IC testing.

The approach for accessing test nodes on a DIB is typically through a bed of nails or flying probe test setup that interfaces with the test infrastructure. The test infrastructure typically includes test instruments (e.g., external test and measurement equipment such as a JTAG controller, a signal source meter, and a multimeter) and a hardware platform. The hardware platform provides an interface with the test instruments and the DIB. The test instruments can provide test signals, such as voltages, currents or Boundary Scan mixed-signal data (compliant with Institute of Electrical and Electronic Engineers, or IEEE, standard 1149.4) to be applied to the test board and take resulting measurements to test the DIB.

### SUMMARY OF THE DISCLOSURE

To address the above-discussed deficiencies of the prior art the invention provides a test definer. In one embodiment, the test definer includes: (1) a circuit builder configured to generate a representative circuit of the PCB based on schematic information thereof, (2) a circuit organizer configured to partition the representative circuit into testable sub-circuits and (3) a specification generator configured to automatically determine functionality tests for the PCB based on the sub-circuits, obtain expected values from the functionality tests and generate platform-independent specifications representing the functionality tests and the expected values.

In another aspect, the disclosure provides a method for automatically determining functional tests for a PCB having analog components. In one embodiment, the method includes: (1) generating a representative circuit of a PCB based on schematic information thereof, (2) partitioning the representative circuit into testable sub-circuits, (3) automatically determining functionality tests for the PCB based on the sub-circuits and (4) automatically generating platform-independent specifications representing the functionality tests.

In yet another aspect, the disclosure provides a test system for an analog PCB. In one embodiment, the test system includes: (1) a test definer and (2) test translator configured to extract test information from the platform-independent specifications and generate functional tests from the platform-independent specifications for the PCB according to a designated test-platform. The test definer includes: (1A) a circuit builder configured to generate a representative circuit of the PCB based on schematic information thereof, (1B) a circuit organizer configured to partition the representative circuit into testable sub-circuits and (1C) a specification generator configured to determine a set of tests for functionality testing of the PCB based on the sub-circuits, obtain expected values from the set of tests and generate platform-independent specifications representing the set of tests and the expected values.

### BRIEF DESCRIPTION OF THE DRAWINGS

For a more complete understanding of the invention, reference is now made to the following descriptions taken in conjunction with the accompanying drawings, in which:

FIG. 1 illustrates a block diagram of an embodiment of a test definer constructed according to the principles of the invention;

FIG. 2 illustrates an example of a typical circuit on a mixed signal PCB;

FIG. 3 illustrates a block diagram of an embodiment of a system for testing a printed circuit board including a test definer constructed according to the principles of the invention;

FIG. 4 illustrates a block diagram of an embodiment of a test translator constructed according to the principles of the invention;

FIG. 5 illustrates a diagram of an embodiment of a system for testing a device interface board constructed according to the principles of the invention; and

FIG. 6 illustrates a flow diagram of an embodiment of a method of automatically determining functional tests for a PCB having analog components carried out according to the principles of the invention.

### DETAILED DESCRIPTION

Although the importance of bench characterization is well understood, test engineers currently do not have the proper set of tools to verify that a new, repaired, reworked, or returned-to-service DIB is fault-free. What would be useful in the art is an improved method or system to verify the operation and configuration of mixed-signal or analog printed circuit boards, such as DIBs. The disclosure provides a tool for automating testing of PCBs having analog components (e.g., mixed signal boards including analog and digital components). The tool is an automated functional specification generator that is IEEE 1149.4 compliant. The tool automatically generates test specifications based on schematic information of the PCB. The test specifications are generic specifications that are independent of the hardware platform used for testing. As such, the test specifications can be translated to specific instructions for a specific platform to provide functional testing for a PCB having analog components (hereinafter referred to as an analog PCB). Functional tests are used, for example, to verify component values of an analog PCB, functionality (where applicable, e.g., relays), connectivity, short circuits and open circuits.

The disclosure provides automated test generation and execution to avoid labor intensive and time-consuming manual programming. In addition to the schematic information, the disclosed tool automatically generates a functional test program for board verification using PCB specific constraints and accessibility provided by the test hardware and instrument automation tools. The novel tool can allow reduction of time-to-market for PCBs in comparison with the existing techniques for mixed signal board testing.

As an example, the disclosure provides an embodiment of a system that automatically generates, translates and tests an analog DIB using a particular IEEE 1149.4 based hardware platform. The IEEE 1149.4 test specification for mixed-signal boundary-scan testing provides a reliable, accurate measurement bus. In the discussed IEEE 1149.4 test system, node access for testing a DIB is through a device under test (DUT) socket and edge-connectors, enabling functional testing of the DIB. Additionally, the disclosed embodiment for testing an analog DIB includes a socket signal extender (SSE) which is disclosed in more detail in U.S. patent application Ser. No. 11/675,558.

Using the DIB netlist and bill of materials (BOM), the tool builds a network representing the DIB schematic. Details of the IEEE 1149.4 switch matrix hardware infrastructure are also incorporated in this network. The network is then logically partitioned into smaller testable sub-circuits. The components are modeled and tests are generated based on the topology and the nature of components in the sub-circuit. In the disclosed embodiment, the tool also decides the forcing and sensing configuration to be used on the hardware platform. Finally, the tool generates pseudo-code that contains complete test specifications for functional testing of the DIB.

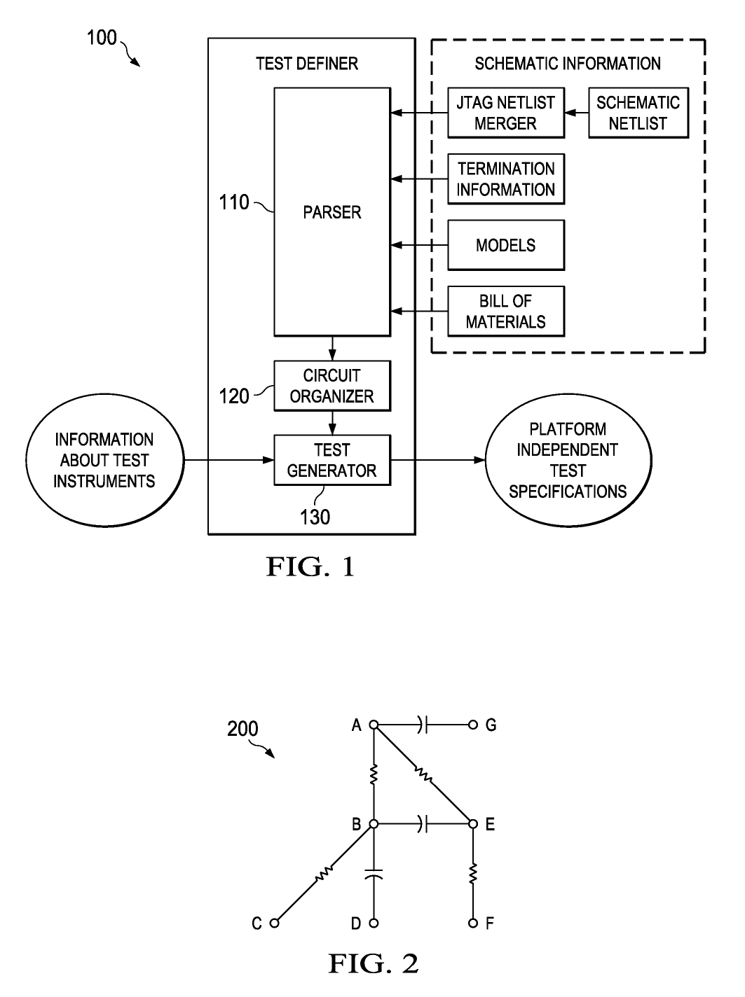

FIG. 1 illustrates a block diagram of an embodiment of a test definer 100 constructed according to the principles of the invention. The test definer 100 automatically determines functional tests for an analog PCB and generically represents the functional tests with test specifications. The test definer 100 may be a dedicated apparatus constructed of special-purpose hardware employing a series of operating instructions which direct its operation. In alternative embodiments, the test definer 100 may be implemented on a general purpose computing device directed by a sequence of operating instructions to determine and represent the functional tests. The test definer 100 includes a circuit builder 110, a circuit organizer 120 and a specification generator 130.

The circuit builder 110 is configured to generate a representative circuit of the PCB based on schematic information of the PCB. The circuit builder 110 receives the schematic information which includes, but is not limited to, a schematic netlist, a JTAG netlist merger, a BOM and a model file of the PCB. The circuit builder 110 can input at least some of the schematic information by exporting it from a design tool used to design the PCB, such as OrCAD® (a design tool commercially available from Cadence Design Systems, Inc., of San Jose, Calif.). The circuit builder 110 can read a model file of the PCB to obtain the component information. The model file can be a Simulation Program With Integrated Circuit Emphasis, or SPICE, model file.

The circuit builder 110 may also receive inputs regarding constraints of the PCB to include in building the representative circuit. The constraints may include, for example, the available terminations for the PCB. The constraint information may be entered manually to the circuit builder 110 via a user interface such as a keyboard. The constraint information is carried forward and used in the generation of testable sub-circuits.

The circuit organizer 120 is configured to partition the representative circuit into testable sub-circuits. The representative circuit is partitioned into testable sub-circuits based on the availability of nodes for stimulating and measuring test signals. A testable sub-circuit is a path of the representative circuit between a start node and a termination node. The partitioned testable sub-circuits are classified based on the type of components, the interconnection topology in the sub-circuit and availability of interface nodes. An interface node is a forcing node for applying a signal, voltage, etc., or sensing node for measuring an output. FIG. 2 illustrates an example of a typical circuit on a mixed signal PCB. To partition such a circuit, the circuit organizer 120 may employ a partition algorithm that operates as described below.

First, a node is chosen that has a termination. This node is then marked as visited and recognized as a start node (node A). Second, components linked to the start node are then found and grouped together as a single block. For example, nodes B, E and G of FIG. 2 are connected to start node A. Third, step two is repeated for all of the nodes in the previously grouped block until another termination node is encountered. Each of the visited nodes are marked. For example, node B is connected to nodes C, D and E. Nodes C and D are determined to be termination nodes. Fourth, a path is marked between the start node A and a termination node as a testable sub-circuit. For example, paths ABC and ABD are identified as partitioned, sub-circuits. Steps 3 and 4 are repeated until all the nodes of the circuit are marked as visited. The other testable sub-circuits in FIG. 2 include AG and AEF. Thus, in FIG. 2, the circuit organizer would identify four testable sub-circuits: ABC, ABD, AG and AEF.

The specification generator 130 is configured to determine functionality tests for the PCB based on the testable sub-circuits, obtain expected values from the functionality tests and generate platform-independent specifications representing the functionality tests and the expected values. The specification generator 130 generates pseudo-code that contains information for testing the PCB. The specification generator 130 generates the test specifications based on the testable sub-circuits including the type of components, the interconnection topology in the sub-circuit and the availability of forcing/sensing nodes. Additionally, the specification generator 130 considers the programmable capabilities of the test equipment when generating the test specifications. The test definer 100 may receive information regarding test equipment via user input. A user interface such as a keyboard may be used to input the information.

The specification generator 130 may operate by first examining the testable sub-circuits for components that can be modeled. The specification generator 130 can then replace the components with the models for further simulations. For example, diodes in forward bias configurations can be replaced by a low value resistor for simulation. Also, the specification generator 130 can evaluate the effective values of passive components for each sub-circuit by identifying the configuration (series/parallel) in which the passive components are connected.

The specification generator 130 generates test that can be broadly classified as DC tests, AC tests and transient tests. The tests are defined for different topologies of circuits that are identified after circuit partition. For sub-circuits that contain only passive elements, DC tests are generated. The DC tests are usually either a force current measure voltage (FCMV) test or a force voltage and measure current (FVMC) test. The force values are based on the component values and also the programmability range of the test instruments.

As noted, the specification generator 130 may also use AC tests and transient tests. The specification generator 130 tests circuits containing capacitors with transient analysis. Other active component sub-circuits and configurations, such as resistors and capacitors in series, are tested with AC or functional tests.

Another important task performed by the specification generator 130 is to simulate the testable sub-circuits with the forcing conditions generated and obtain expected measurement values for the tests. Thus, the specification generator 130 simulates the generated tests using a simulator to obtain nominal expected measurement values. In one embodiment, the specification generator 130 may use a Berkeley SPICE simulator to simulate the tests. Depending on the tolerance of the components and also the measurement inaccuracies introduced because of the hardware setup, both the upper and lower limits for the expected measurement values are calculated. The specification generator 130 may use a SPICE simulation sequence including the following steps:

1. Read sub-circuits and test conditions passed.

2. Read the test instruments limitations.

3. Generate the SPICE source file.

4. Generate a command file to run SPICE simulation.

5. Invoke SPICE and record results.

6. Evaluate the upper and lower values of measurement results depending on the output of the SPICE simulation.

7. Pass the expected value and limits to the specification generator 130.

The test types, expected output values, and configuration of the tester hardware which includes forcing and termination pin names (e.g., interface nodes) are summarized in the test specification in pseudo-code. The test specification is in a generic form requiring a translator that can extract all the information about tests therefrom and translate the test specifications to tester specific language for actual testing of the PCB.

Table 1 shows a sample test specification in pseudo-code for capacitor and relay testing.

TABLE 1
Sample Test Specification in Pseudo-Code

*****CAPACITOR ONLY TEST*****
CONDITION (circuit id = 1013, test type = CAP TEST, test pin =
CH-U1-M2, must be grounded pogo pin = GND)
FCMVDT (forced current = 1e−005, range of voltage =
“.range_vi(0.5}.”, driving time = 0.05, driving pin = CH-U1-
M14, pin type = JTAGDOT4)
COMPARE_LIMITS (lower limit = 0.45 V, upper limit = 0.55 V,
circuit id = 1013, tested components = “C5”, effective cap
value = 1e−006, tolerance = 10%, effective low = 9e−007,
effective high = 1.1e−006)
*****TEST ON CIRCUIT WITH RELAY*****
RELAY ON (K21 , K20>
FCMV (forced current = 1.0000000e−003 A, driving pin = CH-U1-
D2, pin type = JTAGDOT4, grounded pin = CH-J1-B25)
COMPARE_LIMITS (lower limit = 0.9009 V, upper limit = 1.1011 V,
nominal value = 1.001000e+000, circuit id = 300900, tested
components = K21 , K20)
RELAY OFF (K21 , K20)

The test specification is in user-readable form as shown and includes the following information.

1. Type of test: This is dictated by the circuit topology and components.

2. Test conditions: This includes information required for preconditioning the circuit. For example, information about nodes needing to be connected to ground, the configuration on the PCB and the relays that need to be turned ON/OFF.

3. Forcing conditions: The values of current, voltage or AC signal that needs to be forced on to the PCB.

4. Configuration of tester hardware: This specifies the test channels from the hardware tester for forcing and sensing.

5. Expected value and limits for measurement: The results of the simulation and calculated upper and lower bound values.

6. The identity of the component to be tested.

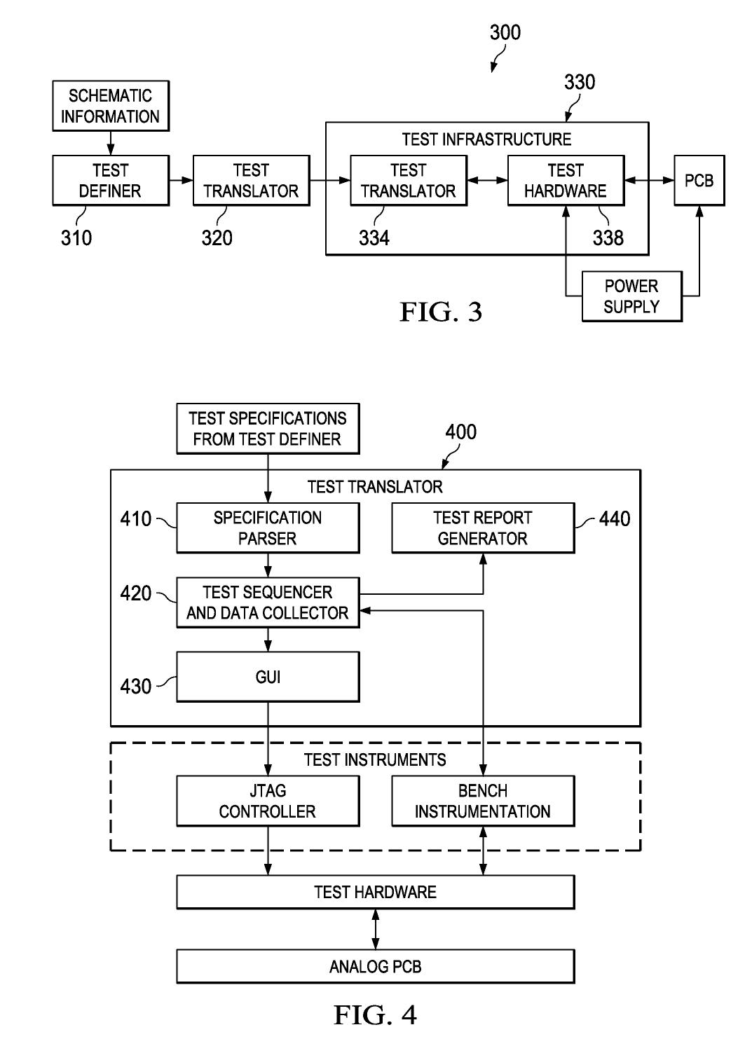

FIG. 3 illustrates a block diagram of an embodiment of a system 300 for testing a PCB including a test definer constructed according to the principles of the invention. The system 300 includes a test definer 310, a test translator 320 and a test infrastructure 330.

The test definer 310 is configured to analyze schematic information of the PCB and generate test specifications for functional testing of the PCB. The test definer 310 may be configured as the test definer 100 in FIG. 1.

The test translator 320 is configured to receive the test specifications from the test definer 310 and based thereon direct functional testing of the PCB. The test translator 320 may be a dedicated apparatus constructed of special-purpose hardware employing a series of operating instructions which direct its operation. In alternative embodiments, the test translator 320 may be implemented on a general purpose computing device directed by a sequence of operating instructions. In some embodiments, the test definer 310 and the test translator 320 may be located in the same computing device.

The test infrastructure 330 applies the necessary signals and takes the needed measurements to perform functional testing of the PCB. The test infrastructure 330 includes test instruments 334 and test hardware 338. The test instruments 334 may be conventional test equipment including a JTAG controller, a source meter and a multimeter. In other embodiments, other or additional test equipment may be used to perform the functional testing. A power supply is used to provide power for both the test hardware 338 and the PCB being tested.

The test hardware 338 provides an interface between the test instruments 334 and the PCB. The test hardware 338 may include a conventional hardware platform having a test bed such as a JTAG DOT 4 compliant test bed. The test bed can have connection points for connecting to the test instruments 334 and to the PCB. The connection points may include conventional SMA connectors. The test bed may also include IEEE 1149.4 compliant System Test Access (STA) devices such as an STA 400 commercially available from National Semiconductor Corporation of Santa Clara, Calif., that allows sourcing or measuring of signals through IEEE 1149.4 compliant controllable analog busses. Test signals and measurements can be routed through the test bed via the connecting points. The test hardware 338 may connect to the PCB through an interface such as a DUT socket.

Since the test specifications generated by the test definer 310 are generic, the test translator 320 automatically translates the test specifications into functional tests for a designated test system such as the test infrastructure in FIG. 3. The test translator 320 is discussed further with respect to FIG. 4.

FIG. 4 illustrates a block diagram of an embodiment of a test translator 400 constructed according to the invention. The test translator 400 translates the generic test specifications into tester specific language for running the test and data collection. The test translator 400 includes a specification parser 410, a test sequencer and data collector (test sequencer) 420, a graphical user interface (GUI) 430 and a test report generator 440.

The specification parser 410 extracts test information such as the source node, termination node and measurement conditions (e.g., expected values, acceptable limits, components tested) from the test specifications generated by a test definer. The source node and termination node may be the interface nodes of the sub-circuits. These parameters are organized in the format required by the test sequencer 420.

The test sequencer 420 controls the test instruments and the GUI 430 to perform the measurements defined in the output of the specification parser 410. The GUI 430 may be an IEEE 1149.4 compliant GUI. The test instruments may include a JTAG controller and bench instruments such as a source meter and a multimeter. To setup a measurement, the test sequencer 420 typically connects a source pin to a source meter and connects a termination pin to ground. Next, a command is sent to the test instruments automatically to stimulate and measure the voltage/current. The measurement results are compared against the respective limits to determine the status of the test. Each of the results can then be stored in a database.

The GUI 430 uses the netlist file of the PCB to map the STA devices of the test hardware to the appropriate test instruments. For example, the GUI 430 may automatically map STA 400 ports of the JTAG controller to STA 400 devices of the test hardware according to the test specifications from a test definer. The activation of test channels in the STA 400 can be accomplished using the JTAG controller. Each pin of the test hardware can be connected to the AT1 bus, the AT2 bus or Virtual Ground of the STA 400. The test translator 400 can control the source meter and a multimeter to perform the tests on the PCB through analog busses. The JTAG controller may be a JTAG controller commercially available from JTAG Technologies Inc., of Stevensville, Md.

The test report generator 440 provides test reports from the testing performed on the PCB. The test reports may include the measured values, pass or fail test status and components tested. The failure information can then be used to determine problem areas and find defective components of the PCB.

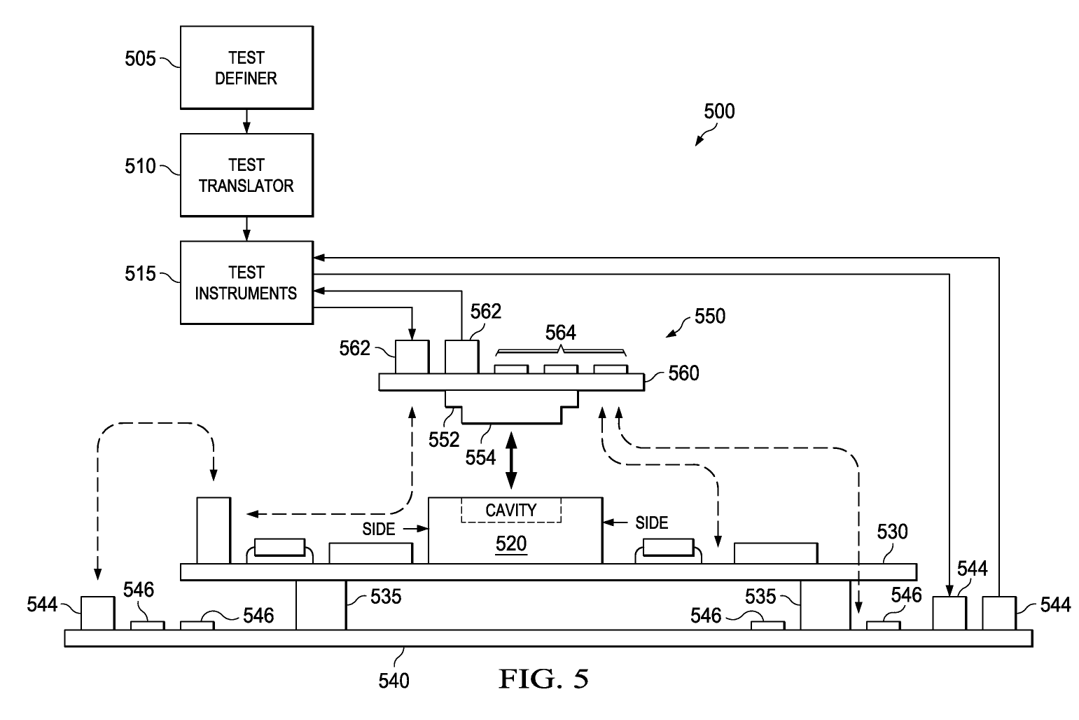

FIG. 5 illustrates a diagram of an embodiment of a system 500 for testing a DIB including a test definer constructed according to the principles of the invention. The system 500 includes a test definer 505, a test translator 510, test instruments 515, a test socket 520, a DIB 530, a test bed 540 and a SSE 550.

The test system 500 is configured to allow the application of test signals designed for post-assembly testing of the DIB 530 and to measure the responses. The test signals may be supplied from the test instruments 515 which can be conventional test instruments. The test translator 510 can direct the testing of the DIB based on test specification derived by the test definer 505. The test translator 510 can direct the test instruments 515 to provide test signals to the test bed 540 or the SSE 550. The test instruments 515 may include a current source, a voltage source or a JTAG compliant source configured to provide Boundary Scan technology in accordance with IEEE 1149.4. The test instruments 515 may be separate components or may be contained in a single enclosure. The test instruments 515 may be coupled to the test bed 540 and the SSE 550 via SMA connections. The test definer 505 and the test translator 510 may be configured as the test definer 310 and the test translator 320 discussed previously.

The test socket 520 may be a conventional test socket that is attached to the DIB 530 and has electrical contacts that are connected to the hardware of the DIB 530. One skilled in the art will understand the test socket 520 and the electrical and mechanical coupling of the test socket 520 to the DIB 530. The test socket 520 includes a cavity wherein a semiconductor device is placed for testing. The test socket 520 includes contacts (not illustrated) at the base of the cavity that connect the semiconductor device to the DIB 530 when testing the semiconductor device. Instead of the semiconductor device, a SSE 550 can be placed in the cavity to allow testing of the assembled DIB 530 and the connections between the contacts of the test socket 520 and the DIB 530. The SSE 550 is an interface device that allows access to the DIB via the test socket 520. Thus, the hardware and the connections of the DIB 530 and the test socket 520 can be tested before the semiconductor is even ready to be tested.

The DIB 530 is typically a PCB with appropriate hardware sized and configured to test the semiconductor device. The DIB 530 may be a typical DUT board used to test a semiconductor device. The DIB 530 may be a characterization board for characterization testing of the semiconductor device. The DIB 530 may also be a system board to test the functionality of the semiconductor device. The DIB 530 is connected to the test bed 540 by standard connectors 535 configured to provide an electrical path therebetween.

The test bed 540 may be a conventional test bed such as a JTAG DOT 4 compliant test bed. The test bed 540 includes connection points 544 for connecting to the test instruments and to the DIB 530. The connection points 544 may be conventional SMA connectors. The test bed 540 also includes IEEE 1149.4 compliant STA devices, denoted 546, such as an STA 400 that allows sourcing or measuring of signals through IEEE 1149.4 compliant controllable analog busses. Test signals and measurements can be routed through the test bed 540 via the connecting points 544.

The SSE 550 includes a cover 552 having a portion 554 that fits in the cavity of the test socket 520. The SSE 550 includes electrical conductors (not illustrated) such as poge pins that provide an electrical path to the pins of the DIB. The portion 554 electrically consists of the electrical conductors. Accordingly, the only electrical components of the portion 554 are the electrical conductors. The portion 554 does not include logic circuitry. In other words, the portion 554 is free of logic. As such, the portion 354 does not include transistors, combinatorial circuits, gates, etc. Thus, the portion 554 is incapable of performing logical operations or switching.

The SSE 550 includes a probe board 560 coupled thereto. The probe board 560 may be a PCB having through-holes that the electrical conductors pass through. The electrical conductors may be soldered in the through-holes to couple the probe board 560 electrically to the SSE 550. As such, the through-holes of the probe board 560 are arranged in a BGA having a pitch and configuration that matches the BGA of the contacts of the test socket 520. The probe board 560 may sit on top of the cover 552 as the electrical conductors pass through the through-holes of the probe board 560.

The probe board 560 includes connecting nodes 562 coupled to at least one of the electrical conductors by an electrical connector or connectors (not illustrated). The electrical connectors may be electrical traces on the PCB board. The connecting nodes 562 may be SMA connectors or other connectors configured to provide an interface to, for example, the test instruments 515. The number of connecting nodes 562 and the type of nodes can vary. The probe board 560 also includes STA chips 564 such as the STA 400 chips that are coupled to the electrical conductors by the electrical connectors.

Connections from the STA chips 564 to the electrical conductors may be determined based on the desired tests to be performed on the DIB 530. The connections to the electrical conductors may be determined automatically by the test translator 510. An IEEE 1149.4 compliant GUI of the test translator 510 may be used to determine the connections based on a merged netlist of the DIB 530.

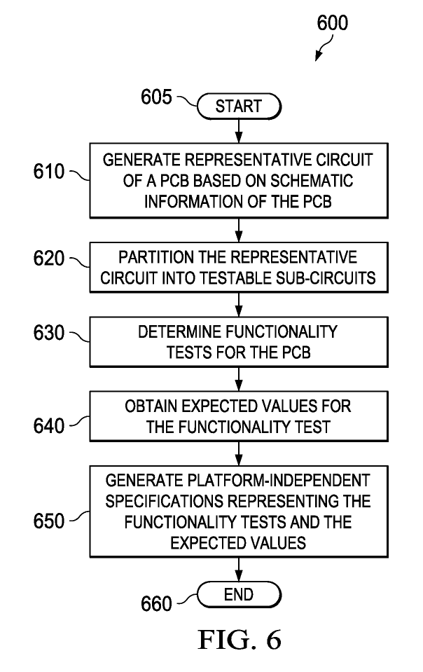

FIG. 6 illustrates a flow diagram of an embodiment of a method 600 of automatically determining functional tests for a printed circuit board (PCB) having analog components carried out according to the principles of the invention. The method 600 may be implemented as a series of operating instructions that direct the operation of a computing device. The method 600 begins in a step 605 with an intent to provide functional tests for an analog PCB.

The method 600 continues by generating a representative circuit of a PCB based on schematic information of the PCB in a step 610. The schematic information may be from a merged schematic netlist. Component information about the PCB may be obtained from BOM and SPICE model files of the PCB. The representative circuit may also be generated based on prior knowledge of available terminations of the PCB.

After generating the representative circuit, the representative circuit is partitioned into testable sub-circuits in a step 620. Functionality tests for the PCB are then determined based on the testable sub-circuits in a step 630. The functionality tests are used to verify component values of an analog PCB, functionality (where applicable, e.g., relays), connectivity, short circuits and open circuits. The functional tests for the PCB may include the following tests: missing device, misalignment, open circuit, short circuit (including adjacent pins), interconnect (including cracked vias), capacitor and resistor values, diode and transistor switching, power supply voltage monitoring, digital switching test, differential pair functional testing and op-amp functional testing.

After determining the functionality tests, expected values for functionality tests are obtained in a step 640. The expected values may be obtained by employing a simulation program to model the testable sub-circuits. A SPICE model program may be used.

Platform-independent specifications representing the functionality tests and the expected values are then generated in a step 650. The test specifications may be in user-readable form and include, for example, the test type, the expected output values and termination names. The method 600 then ends in a step 660.

The above-described system, apparatus and methods may be embodied in or performed by various conventional digital data processors or computers, wherein the computers are programmed or store executable programs of sequences of software instructions to perform one or more of the steps of the methods, e.g., steps of the method of FIG. 6. The software instructions of such programs may be encoded in machine-executable form on conventional digital data storage media, e.g., magnetic or optical disks, random-access memory (RAM), magnetic hard disks, flash memories, and/or read-only memory (ROM), to enable various types of digital data processors or computers to perform one, multiple or all of the steps of one or more of the above-described methods, e.g., one or more of the steps of the method of FIG. 6.

Those skilled in the art to which the invention relates will appreciate that other and further additions, deletions, substitutions and modifications may be made to the described embodiments without departing from the scope of the invention.

What is claimed is:

1. A test definer for automatically determining functional tests for a printed circuit board (PCB) having analog components, comprising:
a circuit builder configured to generate a representative circuit of said PCB based on schematic information thereof;
a circuit organizer configured to partition said representative circuit into testable sub-circuits; and
a specification generator configured to automatically determine functionality tests for said PCB based on said sub-circuits, obtain expected values from said functionality tests and generate platform-independent specifications representing said functionality tests and said expected values.

2. The test definer as recited in claim 1 wherein said specification generator is further configured to generate said platform-independent specifications based on constraints of said PCB and information of test equipment to be used in said functionality tests.

3. The test definer as recited in claim 1 wherein said circuit builder is configured to generate said representative circuit based on schematic information selected from the group consisting of:
a schematic netlist,
a JTAG netlist,
a bill of material, and
a model file.

4. The test definer as recited in claim 1 wherein said circuit builder imports at least some of said schematic information from a design tool used to generate said PCB.

5. The test definer as recited in claim 1 wherein said circuit organizer is configured to partition said representative circuit into said testable sub-circuits based on type of components therein, interconnection topology of said components and availability of forcing/sensing nodes of said testable sub-circuits.

6. The test definer as recited in claim 1 wherein said specification generator is configured to automatically determine DC tests for said sub-circuits having only passive elements.

7. The test definer as recited in claim 1 wherein said specification generator is configured to automatically determine transient tests for said sub-circuits having only capacitors.

8. The test definer as recited in claim 1 wherein said specification generator is configured to automatically determine AC tests for said sub-circuits having active components.

9. The test definer as recited in claim 1 wherein said specification generator is configured to obtain said expected values by simulating said functionality tests.

10. The test definer as recited in claim 1 wherein said specification generator is configured to generate said platform-independent specifications as a human-readable language.

11. A method of automatically determining and representing functional tests for a printed circuit board (PCB) having analog components, comprising:
generating a representative circuit of a PCB based on schematic information thereof;
partitioning said representative circuit into testable sub-circuits;
automatically determining functionality tests for said PCB based on said sub-circuits; and
automatically generating platform-independent specifications representing said functionality tests.

12. The method as recited in claim 11 wherein said generating said platform-independent specifications is further based on constraints of said PCB.

13. The method as recited in claim 11 wherein said schematic information is selected from the group consisting of:
a schematic netlist,
a JTAG netlist,
a bill of material, and
a model file.

14. The method as recited in claim 11 wherein at least part of said schematic information is from a design tool used to generate said PCB.

15. The method as recited in claim 11 wherein said partitioning is based on a type of components of said representative circuit and interconnection topology of said components.

16. The method as recited in claim 11 comprising automatically determining DC tests for said sub-circuits having only passive elements.

17. The method as recited in claim 11 comprising automatically determining transient tests for said sub-circuits having only capacitors.

18. The method as recited in claim 11 comprising automatically determining AC tests for said sub-circuits having active components.

19. The method as recited in claim 11 further comprising obtaining expected values for said functionality tests.

20. The method as recited in claim 19 wherein said generating said platform-independent specifications is further based on said expected values.

21. The method as recited in claim 11 further comprising generating said platform-independent specifications in a user-readable language.

22. A system for providing functional tests for a printed circuit board (PCB) having analog components, comprising:
a test definer including:
a circuit builder configured to generate a representative circuit of said PCB based on schematic information thereof,
a circuit organizer configured to partition said representative circuit into testable sub-circuits, and
a specification generator configured to determine a set of tests for functionality testing of said PCB based on said sub-circuits, obtain expected values from said set of tests and generate platform-independent specifications representing said set of tests and said expected values, and
a test translator configured to extract test information from said platform-independent specifications and generate functional tests from said platform-independent specifications for said PCB according to a designated test-platform.

23. The system as recited in claim 22 wherein said specification generator is further configured to generate said platform-independent specifications based on constraints of said PCB and information of test equipment to be used in said functionality tests.

24. The system as recited in claim 22 wherein said circuit builder is configured to generate said representative circuit based on schematic information selected from the group consisting of:
a schematic netlist,
a JTAG netlist,
a bill of material, and
a model file.

25. The system as recited in claim 22 wherein said circuit organizer is configured to partition said representative circuit into said testable sub-circuits based on availability of interface nodes of said testable sub-circuits.

26. The system as recited in claim 22 wherein said specification generator is configured to automatically determine DC tests for said sub-circuits having only passive elements.

27. The system as recited in claim 22 wherein said specification generator is configured to automatically determine transient tests for said sub-circuits having only capacitors.

28. The system as recited in claim 22 wherein said specification generator is configured to automatically determine AC tests for said sub-circuits having active components.

29. The system as recited in claim 22 wherein said test translator includes a specification parser configured to extract said test information, said test information including a source node, a termination node and a measurement condition.

30. The system as recited in claim 29 wherein said test translator includes a test sequencer and data collector configured to control test instruments for said functional tests based on said extracted test information.
